(19) United States
(12) Patent Application Publication
(10) Pub. No.: US 2019/0083918 A1
(43) Pub. Date: Mar. 21, 2019

(54) MANUFACTURING APPARATUS AND EXHAUST GAS TREATMENT APPARATUS

(71) Applicants: Kabushiki Kaisha Toshiba, Tokyo (JP); Toshiba Electronic Devices & Storage Corporation, Tokyo (JP)

(72) Inventor: Rempei Nakata, Kanazawa Ishikawa (JP)

(21) Appl. No.: 15/901,944

(22) Filed: Feb. 22, 2018

(30) Foreign Application Priority Data
Sep. 19, 2017 (JP) 2017-179330

(51) Int. Cl. B01D 53/00; C30B 25/14; C30B 29/06; B01D 45/08; B01D 47/06; B01D 53/14; B01D 53/18; C23C 16/24; C23C 16/44

(52) U.S. Cl. CPC B01D 53/002; C30B 25/14; C30B 29/06; B01D 45/08; C23C 16/4412; B01D 53/1456; B01D 53/18; C23C 16/24; B01D 47/06

(57) ABSTRACT

A manufacturing apparatus according to an embodiment is a manufacturing apparatus of a semiconductor device or a liquid crystal device including a process chamber discharging exhaust gas, a waste liquid discharger discharging waste liquid including a part of the exhaust gas, a first pipe provided between the process chamber and the waste liquid discharger, having a first opening area in a cross section in a direction perpendicular to a moving direction of the exhaust gas, a second pipe provided between the first pipe and the waste liquid discharger, having a second opening area smaller than the first opening area in a cross section in the direction perpendicular to the moving direction of the exhaust gas, and a third pipe connected to the first pipe, the third pipe supplying a condensing agent having a normal boiling point of equal to or higher than 25° C. to the first pipe.

### CROSS-REFERENCE TO RELATED APPLICATION

This application is based upon and claims the benefit of priority from Japanese Patent Application. No. 2017-179330, filed on Sep. 19, 2017, the entire contents of which are incorporated herein by reference.

### FIELD

Embodiments described herein relate generally to a manufacturing apparatus and an exhaust gas treatment apparatus.

### BACKGROUND

In a manufacturing apparatus for manufacturing a semiconductor device and a liquid crystal device, a film and a pattern are formed on a substrate by using reactive gas. Generally, the film and the pattern are formed by increasing the temperature of the substrate to flow the reactive gas such as a source gas and an etching gas to a process chamber, and then, adjusting a flow rate and a pressure of the reactive gas. The exhaust gas including the reactive gas which has not been consumed in the process chamber and reaction by-product gas generated by reaction is discharged from the process chamber to the outside of the manufacturing apparatus through an exhaust pipe, an exhaust pump, a detoxifying device, and the like.

As the exhaust gas is discharged from the process chamber and passes through the exhaust pipe, the exhaust gas is condensed by being cooled and changed to the droplets or the exhaust gas is sublimated to be the solid particles. There has been a problem in that the droplets and the solid particles cause clogging of the exhaust pipe and a failure of the exhaust pump. Furthermore, there has been a problem in that the solid particles are generated as a product and the exhaust pipe is clogged when the detoxifying device detoxifies the exhaust gas.

If the exhaust pipe is clogged or the exhaust pump fails, it is necessary to maintain the manufacturing apparatus, and an operation rate of the manufacturing apparatus is deteriorated. The droplets and the solid particles derived from the exhaust gas include a substance which generates harmful gas and a substance having ignition properties, which may risk the maintenance work.

### BRIEF DESCRIPTION OF THE DRAWINGS

FIG. 1 is a schematic diagram of an exemplary manufacturing apparatus according to a first embodiment;

FIG. 2 is a schematic diagram of an exemplary manufacturing apparatus according to a second embodiment;

FIG. 3 is a schematic diagram of an exemplary manufacturing apparatus according to a third embodiment;

FIG. 4 is a schematic diagram of an exemplary exhaust gas treatment apparatus according to a fourth embodiment;

FIG. 5 is a schematic diagram of an example of a restrictor and a capturing plate according to the fourth embodiment; and

FIG. 6 is a schematic diagram of an exemplary exhaust gas treatment apparatus according to a fifth embodiment.

### DETAILED DESCRIPTION

A manufacturing apparatus according to one embodiment is a manufacturing apparatus of a semiconductor device or a liquid crystal device including a process chamber discharging exhaust gas; a waste liquid discharger discharging waste liquid including a part of the exhaust gas; a first pipe provided between the process chamber and the waste liquid discharger, the first pipe having a first opening area in a cross section in a direction perpendicular to a moving direction of the exhaust gas; a second pipe provided between the first pipe and the waste liquid discharger, the second pipe having a second opening area smaller than the first opening area in a cross section in the direction perpendicular to the moving direction of the exhaust gas; and a third pipe connected to the first pipe, the third pipe supplying a condensing agent having a normal boiling point of equal to or higher than 25° C. to the first pipe.

The embodiments of the present disclosure are described below with reference to the drawings. In the following description, the same or similar members and the like may be denoted with the same references, and the description regarding members and the like which have been described once is appropriately omitted.

### First Embodiment

A manufacturing apparatus according to a first embodiment is a manufacturing apparatus of a semiconductor device or a liquid crystal device including a process chamber discharging exhaust gas; a waste liquid discharger discharging waste liquid including a part of the exhaust gas; a first pipe provided between the process chamber and the waste liquid discharger, the first pipe having a first opening area in a cross section in a direction perpendicular to a moving direction of the exhaust gas; a second pipe provided between the first pipe and the waste liquid discharger, the second pipe having a second opening area smaller than the first opening area in a cross section in the direction perpendicular to the moving direction of the exhaust gas; and a third pipe connected to the first pipe, the third pipe supplying a condensing agent having a normal boiling point of equal to or higher than 25° C. to the first pipe.

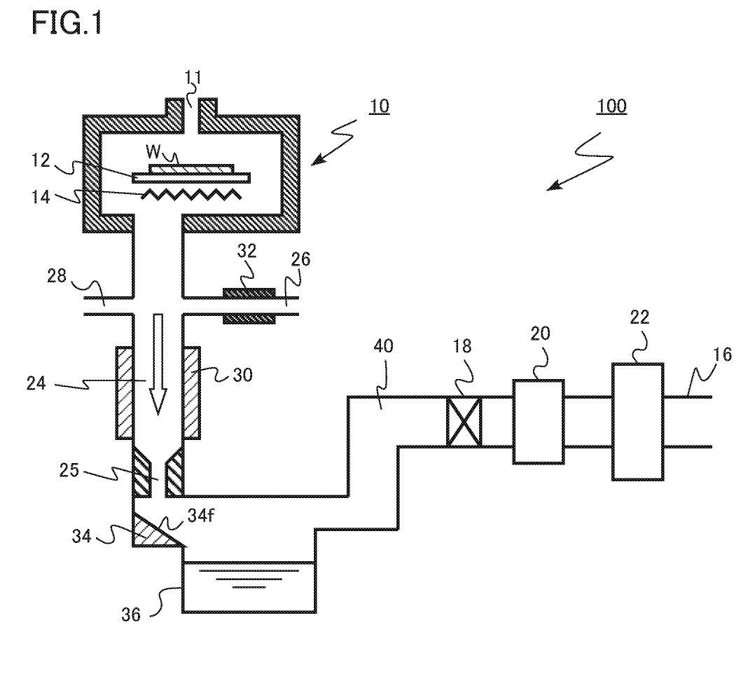

FIG. 1 is a schematic diagram of an exemplary manufacturing apparatus according to the first embodiment. The exemplary manufacturing apparatus according to the first embodiment is a film forming apparatus 100 for manufacturing a semiconductor device. The film forming apparatus 100 according to the first embodiment is a film forming apparatus 100 of single-wafer type for an epitaxial film growth.

The film forming apparatus 100 includes a reaction chamber 10 (process chamber), a gas supply port 11, a stage 12, a heater 14, a discharging unit 16, a pressure regulating valve 18, an exhaust pump 20, a detoxifying device 22, a condensing pipe 24 (first pipe), an accelerating pipe 25 (second pipe), a condensing agent supplying pipe 26 (third pipe), a cleaning gas supplying pipe 28, a temperature adjuster 30, a heater 32, a capturing unit 34 (member), a waste liquid tank 36 (waste liquid discharger), and an exhaust pipe 40.

In the reaction chamber 10, the stage 12 and the heater 14 are provided. A wafer W is placed on the stage 12. The heater 14 heats the wafer W.

The gas supply port 11 is provided in an upper portion of the reaction chamber 10. Source gas is supplied from the gas supply port 11 into the reaction chamber 10.

The reaction chamber 10 is decompressed to a desired pressure at the time of film formation. Exhaust gas including source gas which has not consumed in the reaction chamber 10 and reaction by-products generated by reaction is discharged from the reaction chamber 10.

The condensing pipe 24 is provided between the reaction chamber 10 and the waste liquid tank 36. The condensing pipe 24 is connected to the reaction chamber 10. The condensing pipe 24 has the first opening area (or first cross-sectional area) in the cross section in the direction perpendicular to the moving direction of the exhaust gas (white arrow in FIG. 1). In the film forming apparatus 100, the moving direction of the exhaust gas in the condensing pipe 24 coincides with the direction of gravity.

The exhaust gas discharged from the reaction chamber 10 passes through the condensing pipe 24. The condensing pipe 24 has a function for condensing and liquefying the condensing agent by bringing the condensing agent supplied from the condensing agent supplying pipe 26 into contact with the exhaust gas.

The accelerating pipe 25 is provided between the condensing pipe 24 and the waste liquid tank 36. The condensing pipe 24 is connected to the accelerating pipe 25. The accelerating pipe 25 has the second opening area (or second cross-sectional area) in the cross section in the direction perpendicular to the moving direction of the exhaust gas (white arrow in FIG. 1).

The second opening area is smaller than the first opening area. For example, the second opening area is equal to or larger than 2.5% and equal to or smaller than 20% of the first opening area.

Since the opening area of the accelerating pipe 25 is smaller than that of the condensing pipe 24, the exhaust gas discharged from the reaction chamber 10 is accelerated in the accelerating pipe 25. In other words, the flow velocity of the exhaust gas in the accelerating pipe 25 is faster than that in the condensing pipe 24.

The capturing unit 34 is provided between the accelerating pipe 25 and the waste liquid tank 36. The capturing unit 34 has an inclined surface 34f inclined with respect to the moving direction of the exhaust gas (white arrow in FIG. 1). The inclined surface 34f is inclined toward the waste liquid tank 36. An inclination angle of the inclined surface 34f with respect to the moving direction of the exhaust gas is, for example, equal to or more than 20 degrees and equal to or less than 50 degrees. The capturing unit 34 has a function for capturing droplets included in the exhaust gas by causing the exhaust gas to collide with the inclined surface 34f and flowing the caught droplets into the waste liquid tank 36.

The capturing unit 34 can have a surface perpendicular to the moving direction of the exhaust gas. In this case, it is preferable that the moving direction of the exhaust gas be inclined with respect to the direction of gravity. That is, by disposing the condensing pipe 24, the accelerating pipe 25, and the capturing unit 34 while being inclined with respect to the direction of gravity, the droplets caught by the capturing unit 34 can be collected into the waste liquid tank 36. The structure of the capturing unit 34 can be selected according to a disposing space of each unit in the film forming apparatus 100.

The waste liquid tank 36 is provided between the capturing unit 34 and the exhaust pipe 40. The waste liquid tank 36 is an example of a waste liquid discharger. The waste liquid tank 36 has a function for storing the droplets caught by the capturing unit 34.

The waste liquid tank 36 stores the waste liquid including a part of the exhaust gas. Specially, solid particles and droplets derived from the discharged exhaust gas are included. By removing the waste liquid stored in the waste liquid tank 36, the waste liquid including a part of the exhaust gas is discharged from the film forming apparatus 100.

For example, instead of the waste liquid tank 36, a waste liquid pipe (waste liquid drain) can be provided as a waste liquid discharger. For example, by transferring the solid particles and the droplets caught by the capturing unit 34 to the waste liquid tank 36 provided outside the film forming apparatus 100 through the waste liquid pipe, the waste liquid including a part of the exhaust gas is discharged from the film forming apparatus 100.

The exhaust pump 20 is provided between the exhaust pipe 40 and the discharging unit 16. The exhaust pump 20 decompresses the reaction chamber 10. The exhaust pump 20 is, for example, a vacuum pump.

The pressure regulating valve 18 is provided between the exhaust pipe 40 and the exhaust pump 20. The pressure regulating valve 18 can regulate the pressure in the reaction chamber 10 to a desired pressure.

The detoxifying device 22 is provided between the exhaust pump 20 and the discharging unit 16. The detoxifying device 22 is, for example, a combustion-type detoxifying device.

The detoxifying device 22 detoxifies the exhaust gas discharged from the reaction chamber 10. The detoxified exhaust gas is discharged from the discharging unit 16 to the outside of the film forming apparatus 100.

The condensing agent supplying pipe 26 is connected to the condensing pipe 24. The condensing agent supplying pipe 26 supplies a condensing agent having a normal boiling point of equal to or higher than 25° C. to the condensing pipe 24. The normal boiling point is a boiling point at one atmospheric pressure, that is, at 101325 Pa.

The condensing agent has a function for being condensed and liquefied in the condensing pipe 24 as using minute solid particles and droplets included in the exhaust gas discharged from the reaction chamber 10 as nuclei to form the droplets.

The condensing agent is, for example, perfluoropolyether (PEPE) and benzene (C₆H₆), which is an organic material. As a condensing agent, for example, hexachlorodisilane (Si₂Cl₆) which is an inorganic material can be used.

The normal boiling point of perfluoropolyether (PEPE) is from 55° C. to 270° C., the normal boiling point of benzene (C₆H₆) is 80° C., and the normal boiling point of hexachlorodisilane (Si₂Cl₆) is 144° C.

The heater 32 is provided, for example, around the condensing agent supplying pipe 26. The heater 32 is, for example, a heater using resistance heating.

The heater 32 has a function for heating the condensing agent. For example, a liquid condensing agent is vaporized by the heater 32 and supplied to the condensing pipe 24 as gas.

For example, the temperature adjuster 30 is provided around the condensing pipe 24. The temperature adjuster 30 has a function for adjusting the temperature in the condensing pipe 24.

The temperature adjuster 30 has at least one of a cooling function and a heating function. The temperature adjuster 30 is, for example, a heater using resistance heating. Furthermore, the temperature adjuster 30 is, for example, a water cooling pipe.

By adjusting the temperature by the temperature adjuster 30, the condensing agent in the condensing pipe 24 is maintained to be supersaturated. Since the inside of the condensing pipe 24 is in a decompressed state of less than one atm, the temperature in the condensing pipe 24 is maintained at a temperature lower than the normal boiling point of the condensing agent.

The cleaning gas supplying pipe 28 is connected to the condensing pipe 24. The cleaning gas supplying pipe 28 supplies cleaning gas to the condensing pipe 24. The condensing pipe 24, the accelerating pipe 25, the exhaust pipe 40, and the like are cleaned with the cleaning gas when the film formation in the reaction chamber 10 is not performed.

The cleaning gas is, for example, chlorine trifluoride (ClF₃) gas. For example, the normal boiling point of the cleaning gas is lower than 25° C.

Next, a film forming method by using the film forming apparatus 100 according to the first embodiment is described. A case where a silicon epitaxial film is formed on the wafer N is described as an example.

First, the wafer N is loaded in the reaction chamber 10 and is placed on the stage 12. Next, while hydrogen (H₂) is flowed from the gas supply port 11, and the reaction chamber 10 is decompressed by the exhaust pump 20 so as to be in a decompressed state. The pressure regulating valve 18 regulates the pressure in the reaction chamber 10 to a desired pressure. Furthermore, the heater 14 heats the wafer W, for example, to 1000° C.

Next, the source gas is supplied from the gas supply port 11 into the reaction chamber 10, and a silicon epitaxial film is formed on the surface of the wafer W. The source gas is, for example, dichlorosilane (SiH₂Cl₂), hydrogen. (H₂), or hydrogen chloride (HCl).

When a silicon epitaxial film is formed, gases of chlorosilanes such as trichlorosilane (SiHCl₃), tetrachlorosilane (SiCl₄) tetrachlorodisilane (Si₂H₂Cl₄) hexachlorodisilane (Si₂Cl₆) and octachlorotrisilane (Si₃Cl₈) and chlorosilane polymers (SixHyClz: x is equal to or more than two) may be generated as a reaction by-product. Chlorosilane polymers mean molecular compounds having a main chain in which two or more silicon atoms are bonded and a substituent on the silicon atom is chlorine or hydrogen or a substance in which a plurality of kinds of molecular compounds is mixed.

The reaction by-product gas and the source gas which has not been used to form the film are included in the gas to be discharged from the reaction chamber 10.

The higher the molecular weights of the reaction by-product gas and the source gas are, the higher the boiling point at the same pressure is. For example, the normal boiling point of dichlorosilane which is the source gas is about 8° C. Whereas, the normal boiling point of trichlorosilane is about 31° C., and the normal boiling point of tetrachlorosilane is about 57° C. The normal boiling point of chlorosilane polymers having a larger molecular weight is higher.

When the exhaust gas is discharged outside from the reaction chamber 10, and the gas of chlorosilane polymers having the higher boiling point is condensed and liquefied first to form the droplets. As the exhaust gas is further cooled, the gas of chlorosilane polymers having the lower boiling point and the gas of chlorosilanes having the lower boiling point are condensed and liquefied to form the droplets. In addition, there is a case where gas of some chlorosilane polymers is solidified after being sublimated or liquefied, and then, is changed into solid particles.

During the film formation in the reaction chamber 10, the condensing agent is supplied from the condensing agent supplying pipe 26 to the condensing pipe 24. The condensing agent may be hexachlorodisilane (Si₂Cl₆). Hexachlorodisilane (Si₂Cl₆) is heated by the heater 32 and supplied to the condensing pipe 24 in a vaporized state.

The temperature adjuster 30 adjusts the temperature of hexachlorodisilane supplied to the condensing pipe 24 so as to be supersaturated.

When the exhaust gas contacts hexachlorodisilane which is maintained to be supersaturated, hexachlorodisilane is liquefied as having the droplets and the solid particles included in the exhaust gas as nuclei, and a large droplet of hexachlorodisilane is formed.

The exhaust gas including the hexachlorodisilane droplets is accelerated in the accelerating pipe 25. The hexachlorodisilane droplets in the exhaust gas are accelerated in the accelerating pipe 25.

The accelerated hexachlorodisilane droplet collides with the inclined surface 34f of the capturing unit 34 and is attached to the inclined surface 34f. The hexachlorodisilane droplet attached to the inclined surface 34f flows along the inclined surface 34f, and flows into and is stored in the waste liquid tank 36.

The exhaust gas from which hexachlorodisilane droplets have been removed is detoxified by the detoxifying device 22 and is discharged from the discharging unit 16 to the outside of the film forming apparatus 100.

After the formation of the desired silicon epitaxial film is completed, supply of the source gas into the reaction chamber 10 is stopped, and the temperature of the wafer N is lowered. Subsequently, the wafer is loaded out from the reaction chamber 10.

Next, functions and effects of the first embodiment are described.

In a general film forming apparatus, the exhaust gas including the reaction by-product gas and the source gas which has not been used to form a film is discharged from the reaction chamber to the outside of the manufacturing apparatus through the exhaust pipe, the exhaust pump, the detoxifying device, and the like.

As the exhaust gas is discharged from the reaction chamber and passes through the exhaust pipe, the exhaust gas is condensed by being cooled and changed to the droplets, or the exhaust gas is sublimated to be the solid particles. There has been a problem in that the droplets and the solid particles cause clogging of the exhaust pipe and a failure of the exhaust pump.

If the exhaust pipe is clogged or the exhaust pump fails, it is necessary to maintain the manufacturing apparatus, and an operation rate of the manufacturing apparatus is deteriorated. The droplets and the solid particles derived from the exhaust gas include a substance which generates harmful gas and a substance having ignition properties, which may risk the maintenance work. Therefore, it is desired to prevent the clogging of the exhaust pipe and the failure of the exhaust pump caused by the droplets and the solid particles derived from the exhaust gas.

The film forming apparatus 100 according to the first embodiment includes the condensing agent supplying pipe 26 and the condensing pipe 24 in a path between the reaction chamber 10 and the exhaust pipe 40. The condensing agent may be maintained to be supersaturated in the condensing pipe 24. By contacting the condensing agent which is maintained to be supersaturated with the exhaust gas, the condensing agent is liquefied as having the droplets and the solid particles generated in the exhaust gas as a nucleus, and a large droplet of the condensing agent is formed.

The droplets and the solid particles derived from the exhaust gas are taken in the large droplet of the condensing agent. Accordingly, the droplets and the solid particles derived from the exhaust gas are caught by the capturing unit 34 and stored in the waste liquid tank 36. The exhaust gas from which the droplets and the solid particles derived from the exhaust gas have been removed flows to the exhaust pipe 40, the pressure regulating valve 18, the exhaust pump 20, and the detoxifying device 22. Therefore, it is possible to prevent the clogging of the exhaust pipe and the failure of the exhaust pump.

In particular, in the first embodiment, the droplets and the solid particles derived from the exhaust gas are taken in the large droplet of the condensing agent. Therefore, even when the droplets and the solid particles derived from the exhaust gas are minute, the droplets and the solid particles can be easily collected.

In particular, in the first embodiment, the solid particles, which have no fluidity, get fluidity by being taken in the large droplet of the condensing agent. Therefore, it is possible to flow the droplets from the capturing unit 34 into the waste liquid tank 36 and collect the solid particles.

From the viewpoint of storage and collection of the droplets taken in the condensing agent in the waste liquid tank 36, the condensing agent needs to be a liquid or solid substance under atmospheric pressure. Therefore, the normal boiling point of the condensing agent is equal to or higher than 25° C. which is standard room temperature.

In addition, the condensing agent needs to be a substance which is supersaturated by temperature adjustment by the temperature adjuster 30 under the reduced pressure in the condensing pipe 24. In other words, the condensing agent needs to be a substance of which phase transition from gas to liquid occurs by the temperature adjustment by the temperature adjuster 30 under the reduced pressure in the condensing pipe 24. From viewpoint of bringing the condensing agent into a supersaturated state, it is preferable that the normal boiling point of the condensing agent be higher than 100° C.

In addition, it is preferable that the condensing agent has low reactivity with the droplets and the solid particles derived from the exhaust gas in the exhaust gas.

Depending on the type of the condensing agent and the pressure in the condensing pipe 24, it is determined whether the temperature adjuster 30 heats or cools the condensing agent in the condensing pipe 24.

From the viewpoint of a flow rate adjustment, it is preferable that the condensing agent be heated and supplied to the condensing pipe 24 as gas. However, it is also possible to supply a liquid condensing agent to the condensing pipe 24. In a case where the condensing agent is supplied as liquid, the condensing agent can be vaporized in the condensing pipe 24 which is decompressed. In this case, since the temperature in the condensing pipe 24 is lowered by heat of vaporization, it is preferable to heat the condensing pipe 24 by the temperature adjuster 30 for the heat of vaporization.

In addition, in the first embodiment, the droplets of the condensing agent formed in the condensing pipe 24 are accelerated by providing the accelerating pipe 25. By accelerating the droplets of the condensing agent and colliding the droplets with the capturing unit 34, it is possible to surely catch the droplets of the condensing agent. Therefore, an efficiency of capturing the droplets and the solid particles derived from the exhaust gas is improved.

The second opening area of the accelerating pipe 25 may be equal to or larger than 2.5% and equal to or smaller than 20% of the first opening area of the condensing pipe 24. When the area is smaller than the above range, it is difficult to control the pressure in the reaction chamber 10. In addition, when the area is larger than the above range, the acceleration of the droplet becomes insufficient, and the efficiency of capturing the droplets decreases.

As described above, according to the first embodiment, there can be provided a manufacturing apparatus capable of improving the efficiency of capturing the droplets and the solid particles derived from the exhaust gas and preventing the clogging of the exhaust pipe and the failure of the exhaust pump.

### Second Embodiment

A manufacturing apparatus according to a second embodiment is different from that according to the first embodiment in that the manufacturing apparatus is a batch-type film forming apparatus. The description overlapped with the first embodiment may be partially omitted.

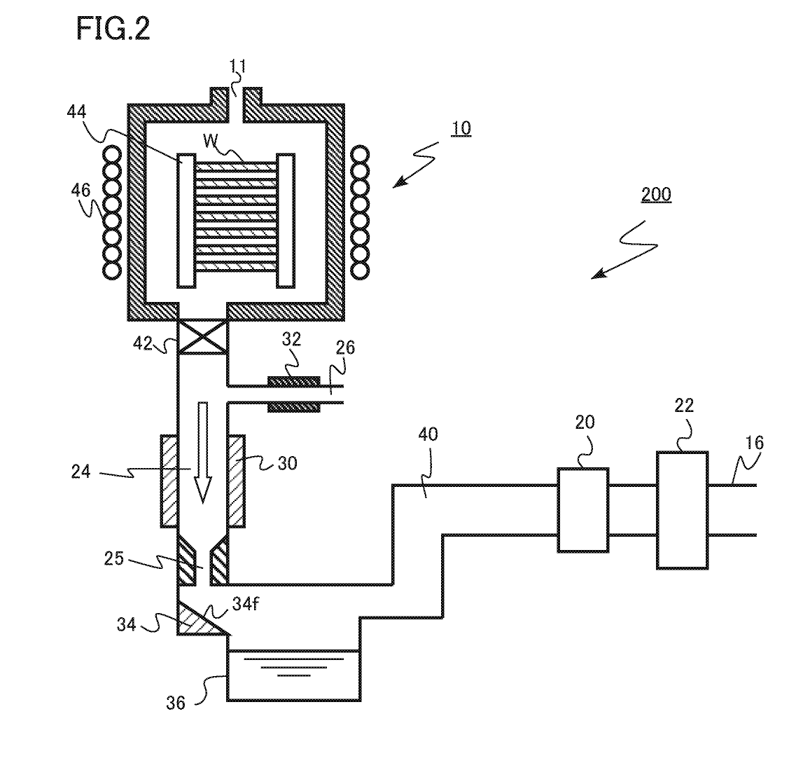

FIG. 2 is a schematic diagram of an exemplary manufacturing apparatus according to the second embodiment. The exemplary manufacturing apparatus according to the second embodiment is a film forming apparatus 200 for manufacturing a semiconductor device. The film forming apparatus 200 according to the second embodiment is a batch-type film forming apparatus.

The film forming apparatus 200 includes a reaction chamber 10 (process chamber), a gas supply port 11, a boat 44, a heater 46, a discharging unit 16, a pressure regulating valve 42, an exhaust pump 20, a detoxifying device 22, a condensing pipe 24 (first pipe), an accelerating pipe 25 (second pipe), a condensing agent supplying pipe 26 (third pipe), a temperature adjuster 30, a heater 32, a capturing unit 34 (member), a waste liquid tank 36 (waste liquid discharger), and an exhaust pipe 40.

The reaction chamber 10 is made of, for example, transparent quartz glass. The boat 44 is provided in the reaction chamber 10. The gas supply port 11 is provided in an upper portion of the reaction chamber 10. Material gas is supplied from the gas supply port 11 into the reaction chamber 10.

The boat 44 can hold a plurality of wafers W. The boat 44 is made of, for example, quartz glass.

The heater 46 is provided around the reaction chamber 10. The heater 46 heats the wafers W placed on the boat 44.

The pressure regulating valve 42 is provided between the reaction chamber 10 and the condensing pipe 24. The pressure regulating valve 42 can decompress the reaction chamber 10 to a desired pressure.

Next, a film forming method by using the film forming apparatus 200 according to the second embodiment is described. A case where a silicon nitride film is formed on the wafer W is described as an example.

First, the wafer W is carried into the reaction chamber 10 and held by the boat 44. Next, the exhaust pump 20 decompresses the reaction chamber 10. The pressure in the reaction chamber 10 is adjusted to the desired pressure by using the pressure regulating valve 42. Furthermore, the heater 46 heats the wafer W to a predetermined temperature.

Next, the source gas is supplied from the gas supply port 11 into the reaction chamber 10, and a silicon nitride film is formed on the surface of the wafer W. The source gas is, for example, dichlorosilane (SiH₂Cl₂) and ammonia (NH₃).

When the silicon nitride film is formed, NH₄Cl is generated as a reaction by-product and included in the exhaust gas discharged from the reaction chamber 10. Since NH₄Cl has a high boiling point, NH₄Cl tends to be sublimated and be solid particles when being cooled.

When the silicon nitride film is formed in the reaction chamber 10, the condensing agent is supplied from the condensing agent supplying pipe 26 to the condensing pipe 24. The condensing agent may be perfluoropolyether (PEPE). The perfluoropolyether is heated by the heater 32 and supplied to the condensing pipe 24 in a vaporized state.

The temperature adjuster 30 adjusts the temperature in the condensing pipe 24 so that perfluoropolyether supplied to the condensing pipe 24 is supersaturated.

When the exhaust gas contacts perfluoropolyether which is maintained to be supersaturated, perfluoropolyether is liquefied as having the solid particle of NH₄Cl included in the exhaust gas as a nucleus, and a large droplet of perfluoropolyether is formed.

The exhaust gas including the perfluoropolyether droplets is accelerated in the accelerating pipe 25. The perfluoropolyether droplets in the exhaust gas are accelerated in the accelerating pipe 25.

The accelerated perfluoropolyether droplet collides with an inclined surface 34f of the capturing unit 34 and is attached to the inclined surface 34f. The perfluoropolyether droplet attached to the inclined surface 34f flows along the inclined surface 34f and flows into and is stored in the waste liquid tank 36.

The exhaust gas from which the perfluoropolyether droplets including the solid particles of NH₄Cl have been removed is detoxified by the detoxifying device 22 and is discharged from the discharging unit 16 to the outside of the film forming apparatus 200.

After the formation of the desired silicon nitride film is completed, supply of the source gas into the reaction chamber 10 is stopped, and the temperature of the wafer W is lowered. Subsequently, the wafer W is carried out from the reaction chamber 10.

There has been a problem in that the solid particles of NH₄Cl included in the exhaust gas cause clogging of the exhaust pipe and a failure of the exhaust pump.

According to the film forming apparatus 200 of the second embodiment, the perfluoropolyether droplet is formed as having the solid particle of NH₄Cl as a nucleus. Since the perfluoropolyether droplets including the solid particles of NH₄Cl have fluidity, it is possible to flow the droplets from the capturing unit 34 into the waste liquid tank 36 and collect the droplets.

As described above, according to the second embodiment, it is possible to provide a manufacturing apparatus capable of preventing the clogging of the exhaust pipe and the failure of the exhaust pump as in the first embodiment.

### Third Embodiment

A manufacturing apparatus according to a third embodiment is a manufacturing apparatus for manufacturing a semiconductor device or a liquid crystal device which includes a process chamber discharging exhaust gas; a waste liquid discharger discharging waste liquid including a part of the exhaust gas; a discharging unit discharging a remaining part of the exhaust gas; a first pipe provided between the process chamber and the waste liquid discharger, the first pipe having a first opening area in a cross section in a direction perpendicular to a moving direction of the exhaust gas; a second pipe provided between the first pipe and the waste liquid discharger, the second pipe having a second opening area smaller than the first opening area in a cross section in the direction perpendicular to the moving direction of the exhaust gas; a first pressure regulator provided between the process chamber and the first pipe, the first pressure regulator controlling a pressure in the process chamber; and a second pressure regulator provided between the waste liquid discharger and the discharging unit, the second pressure regulator controlling a pressure in the first pipe.

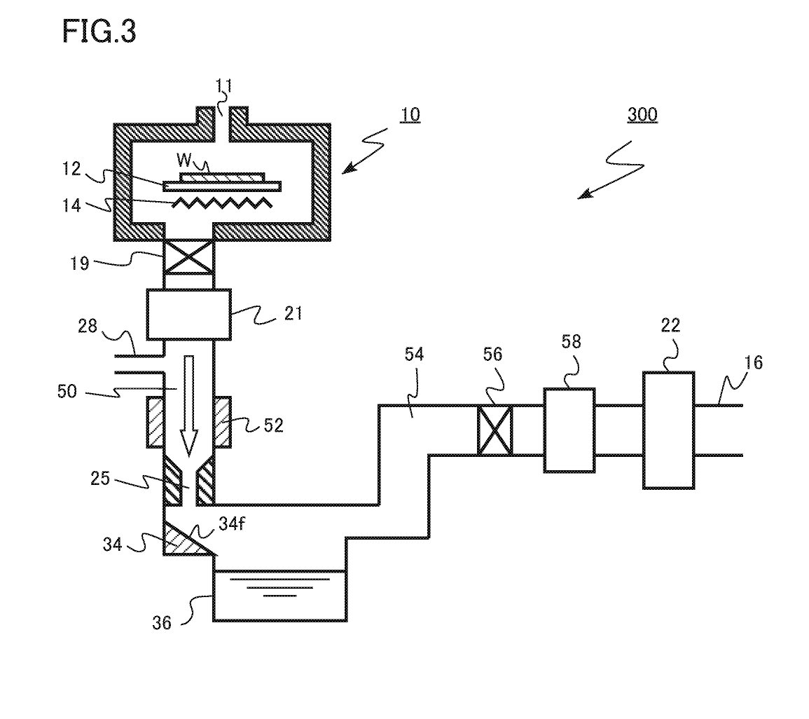

FIG. 3 is a schematic diagram of an exemplary manufacturing apparatus according to the third embodiment. The exemplary manufacturing apparatus according to the third embodiment is a film forming apparatus 300 for manufacturing a semiconductor device. The film forming apparatus 300 according to the third embodiment is a film forming apparatus 300 of single-wafer type for an epitaxial film growth.

The film forming apparatus 300 includes a reaction chamber 10 (process chamber), a gas supply port 11, a stage 12, a heater 14, a discharging unit 16, a first pressure regulating valve 19 (first pressure regulator), a first exhaust pump 21 (first pressure regulator), a detoxifying device 22, a first exhaust pipe 50 (first pipe), an accelerating pipe 25 (second pipe), a cleaning gas supplying pipe 28, a cooling unit 52, a capturing unit 34 (member), a waste liquid tank 36 (waste liquid discharger), a second exhaust pipe 54, a second pressure regulating valve 56 (second pressure regulator), and a second exhaust pump 58 (second pressure regulator).

In the reaction chamber 10, the stage 12 and the heater 14 are provided. A wafer W is placed on the stage 12. The heater 14 heats the wafer W.

The gas supply port 11 is provided in an upper portion of the reaction chamber 10. Source gas is supplied from the gas supply port 11 into the reaction chamber 10.

The reaction chamber 10 is decompressed to a desired pressure at the time of film formation. Exhaust gas including source gas which has not consumed in the reaction chamber 10 and reaction by-products generated by reaction is discharged from the reaction chamber 10.

The first exhaust pump 21 is provided between the reaction chamber 10 and the first exhaust pipe 50. The first exhaust pump 21 decompresses the reaction chamber 10. The first exhaust pump 21 is, for example, a vacuum pump.

The first pressure regulating valve 19 is provided between the reaction chamber 10 and the first exhaust pump 21. The first pressure regulating valve 19 can regulate the pressure in the reaction chamber 10 to a desired pressure.

The first exhaust pump 21 and the first pressure regulating valve 19 form a first pressure regulator.

The first exhaust pipe 50 is provided between the first exhaust pump 21 and the waste liquid tank 36. The first exhaust pipe 50 is connected to the reaction chamber 10. The first exhaust pipe 50 has a first opening area in a cross section in the direction perpendicular to a moving direction of the exhaust gas (white arrow in FIG. 3).

The exhaust gas discharged from the reaction chamber 10 passes through the first exhaust pipe 50.

The accelerating pipe 25 is provided between the first exhaust pipe 50 and the waste liquid tank 36. The first exhaust pipe 50 is connected to the accelerating pipe 25. The accelerating pipe 25 has a second opening area in the cross section in the direction perpendicular to the moving direction of the exhaust gas (white arrow in FIG. 3).

The second opening area is smaller than the first opening area. For example, the second opening area is equal to or larger than 2.5% and equal to or smaller than 20% of the first opening area.

Since the opening area of the accelerating pipe 25 is smaller than that of the first exhaust pipe 50, the exhaust gas discharged from the reaction chamber 10 is accelerated in the accelerating pipe 25. In other words, the flow velocity of the exhaust gas in the accelerating pipe 25 is faster than that in the first exhaust pipe 50.

The capturing unit 34 is provided between the accelerating pipe 25 and the waste liquid tank 36. The capturing unit 34 has an inclined surface 34f inclined with respect to the moving direction of the exhaust gas (white arrow in FIG. 3). The inclined surface 34f is inclined toward the waste liquid tank 36. An inclination angle of the inclined surface 34f with respect to the moving direction of the exhaust gas is, for example, equal to or more than 30 degrees and equal to or less than 60 degrees. The capturing unit 34 has a function for capturing the droplets included in the exhaust gas and flowing the caught droplets into the waste liquid tank 36.

The waste liquid tank 36 is provided between the capturing unit 34 and the second exhaust pipe 54. The waste liquid tank 36 is an example of a waste liquid discharger. The waste liquid tank 36 has a function for storing the droplets caught by the capturing unit 34.

The waste liquid tank 36 stores the waste liquid including a part of the exhaust gas. Specifically, solid particles and minute droplets derived from the discharged exhaust gas are included. By removing the waste liquid stored in the waste liquid tank 36, the waste liquid including a part of the exhaust gas is discharged from the film forming apparatus 300.

For example, instead of the waste liquid tank 36, a waste liquid pipe (waste liquid drain) can be provided as a waste liquid discharger. For example, by transferring the droplets caught by the capturing unit 34 to the waste liquid tank provided outside the film forming apparatus 300 through the waste liquid pipe, the waste liquid including a part of the exhaust gas is discharged from the film forming apparatus 300.

The second exhaust pump 58 is provided between the second exhaust pipe 54 and the discharging unit 16. The second exhaust pump 58 decompresses the first exhaust pipe 50. The second exhaust pump 58 is, for example, a vacuum pump.

The second pressure regulating valve 56 is provided between the second exhaust pipe 54 and the second exhaust pump 58. The second pressure regulating valve 56 can regulate the pressure in the first exhaust pipe 50 to a desired pressure. The second pressure regulating valve 56 regulates the pressure in the first exhaust pipe 50 to be higher than that in the reaction chamber 10.

The second exhaust pump 58 and the second pressure regulating valve 56 form a second pressure regulator. The second pressure regulator provided between the waste liquid tank 36 and the discharging unit 16.

The detoxifying device 22 is provided between the second exhaust pump 58 and the discharging unit 16. The detoxifying device 22 is, for example, a combustion-type detoxifying device.

The detoxifying device 22 detoxifies the exhaust gas discharged from the reaction chamber 10. The detoxified exhaust gas is discharged from the discharging unit 16 to the outside of the film forming apparatus 300.

The cooling unit 52 is provided around the first exhaust pipe 50. The cooling unit 52 is, for example, a water cooling pipe. The cooling unit 52 has a function for cooling the exhaust gas in the first exhaust pipe 50.

The cleaning gas supplying pipe 28 is connected to the first exhaust pipe 50. The cleaning gas supplying pipe 28 supplies cleaning gas to the first exhaust pipe 50. The first exhaust pipe 50, the accelerating pipe 25, the second exhaust pipe 54, and the like are cleaned with the cleaning gas when the film formation in the reaction chamber 10 is not performed. The cleaning gas is, for example, chlorine trifluoride (ClF₃) gas.

Next, a film forming method by using the film forming apparatus 300 according to the third embodiment is described. A case where a silicon epitaxial film is formed on the wafer W is described as an example.

First, the wafer W is loaded in the reaction chamber 10 and is placed on the stage 12. Next, while hydrogen (H₂) is flowed from the gas supply port 11, and the reaction chamber 10 is decompressed by the first exhaust pump 21 so as to be in a decompressed state. The first pressure regulating valve 19 regulates the pressure in the reaction chamber 10 to a desired pressure. The pressure in the reaction chamber 10 is, for example, 10 kPa.

The second exhaust pump 58 decompresses the first exhaust pipe 50. The second pressure regulating valve 56 regulates the pressure in the first exhaust pipe 50 to a desired pressure. The pressure in the first exhaust pipe 50 is made higher than the pressure in the reaction chamber 10. The pressure in the first exhaust pipe 50 is, for example, 40 kPa.

Next, the heater 14 heats the wafer W, for example, to 1000° C.

Next, the source gas is supplied from the gas supply port 11 into the reaction chamber 10, and a silicon epitaxial film is formed on the surface of the wafer. W. The source gas is, for example, dichlorosilane (SiH₂Cl₂), hydrogen (H₂), or hydrogen chloride (HCl).

When an epitaxial film is formed, gases of chlorosilanes such as trichlorosilane (SiHCl₂), tetrachlorosilane (SiCl₄), tetrachlorodisilane (Si₂H₂Cl₄), hexachlorodisilane (Si₂Cl₆), and octachlorotrisilane (Si₃Cl₈) and chlorosilane polymers (SixHyClz: x is equal to or more than two) are generated as a reaction by-product. Chlorosilane polymers mean molecular compounds having a main chain in which two or more silicon atoms are bonded and a substituent on the silicon atom is chlorine or hydrogen or a substance in which a plurality of kinds of the molecular compounds is mixed.

The reaction by-product gas and the source gas which has not been used to form the film are included in the gas to be discharged from the reaction chamber 10.

The higher the molecular weights of the reaction by-product gas and the source gas are, the higher the boiling point at the same pressure is. For example, the normal boiling point of dichlorosilane which is the source gas is about 8° C. Whereas, the normal boiling point of trichlorosilane is about 31° C., and the normal boiling point of tetrachlorosilane is about 57° C. The normal boiling point of chlorosilane polymers having a larger molecular weight is higher. The normal boiling point is a boiling point at one atmospheric pressure, that is, at 101325 Pa.

When the exhaust gas is discharged from the reaction chamber 10 to the first exhaust pipe 50, the pressure of the exhaust gas is increased. Furthermore, the exhaust gas is cooled by the cooling unit 52. Therefore, first, the gas of chlorosilane polymers having a high boiling point is condensed and liquefied, and forms droplets. As the exhaust gas is further cooled, the gas of chlorosilane polymers having the lower boiling point and the gas of chlorosilanes are condensed and liquefied, and form the droplets.

The exhaust gas including the droplets derived from the exhaust gas is accelerated in the accelerating pipe 25. The droplets derived from the exhaust gas in the exhaust gas are accelerated in the accelerating pipe 25.

The accelerated droplet collides with the inclined surface 34f of the capturing unit 34 and is attached to the inclined surface 34f. The droplet attached to the inclined surface 34f flows along the inclined surface 34f and flows into and is stored in the waste liquid tank 36.

The exhaust gas from which droplets derived from the exhaust gas have been removed is detoxified by the detoxifying device 22 and is discharged from the discharging unit 16 to the outside of the film forming apparatus 300.

After the formation of the desired silicon epitaxial film is completed, supply of the source gas into the reaction chamber 10 is stopped, and the temperature of the wafer W is lowered. Subsequently, the wafer W is carried out from the reaction chamber 10.

Next, functions and effects of the third embodiment are described.

In a general film forming apparatus, the exhaust gas including the reaction by-product gas and the source gas which has not been used to form a film is discharged from the reaction chamber to the outside of the manufacturing apparatus through the exhaust pipe, the exhaust pump, the detoxifying device, and the like.

As the exhaust gas is discharged from the reaction chamber and passes through the exhaust pipe, the exhaust gas is condensed by being cooled and changed to the droplets, and is sublimated to be the solid particles. There has been a problem in that the droplets and the solid particles cause clogging of the exhaust pipe and a failure of the exhaust pump.

If the exhaust pipe is clogged or the exhaust pump fails, it is necessary to maintain the manufacturing apparatus, and an operation rate of the manufacturing apparatus is deteriorated. The droplets and the solid particles derived from the exhaust gas include a substance which generates harmful gas and a substance having ignition properties, which may risk the maintenance work. Therefore, it is desired to prevent the clogging of the exhaust pipe and the failure of the exhaust pump due to the droplets and the solid particles derived from the exhaust gas.

The film forming apparatus 300 according to the third embodiment includes the first pressure regulator including the first exhaust pump 21 and the first pressure regulating valve 19 and the second pressure regulator including the second exhaust pump 58 and the second pressure regulating valve 56.

By having the first pressure regulator and the second pressure regulator, the pressure in the first exhaust pipe 50 can be made higher than the pressure in the reaction chamber 10. Therefore, the source gas and the reaction by-product gas having a boiling point lower than that in a case where the pressure in the first exhaust pipe 50 is equal to the pressure in the reaction chamber 10 can be liquefied. The size of the droplet generated by liquefying the source gas and the reaction by-product gas can be larger than that in a case where the pressure in the first exhaust pipe 50 is equal to the pressure in the reaction chamber 10.

The droplet is caught by colliding with the inclined surface 34f of the capturing unit 34. The caught droplet is discharged to the outside of the film forming apparatus 300 by being stored in the waste liquid tank 36. By increasing the size of the droplet, a capturing efficiency by the capturing unit 34 is improved.

In addition, in the third embodiment, the droplets formed in the first exhaust pipe 50 are accelerated by providing the accelerating pipe 25. By accelerating the droplets and colliding the droplets with the capturing unit 34, it is possible to catch the droplets. Therefore, the efficiency of capturing the droplets derived from the exhaust gas is improved.

The second opening area of the accelerating pipe 25 is equal to or larger than 2.5% and equal to or smaller than 20% of the first opening area of the first exhaust pipe 50. When the area is smaller than the above range, it is difficult to control the pressure in the reaction chamber 10. In addition, when the area is larger than the above range, the acceleration of the droplet becomes insufficient, and the efficiency of capturing the droplets decreases.

In the third embodiment, by cooling the exhaust gas by the cooling unit 52, the source gas and the reaction by-product gas having a lower boiling point can be liquefied. It is possible to further increase the size of the droplet to be generated by liquefying the source gas and the reaction by-product gas. Therefore, the efficiency of capturing the droplets is further improved.

As described above, according to the third embodiment, there can be provided a manufacturing apparatus capable of improving the efficiency of capturing the droplets derived from the exhaust gas and preventing the clogging of the exhaust pipe and the failure of the exhaust pump.

### Fourth Embodiment

An exhaust gas treatment apparatus according to a fourth embodiment includes a spray tower having a first opening area in a cross section in a direction perpendicular to a moving direction of exhaust gas; a spray nozzle provided in the spray tower, the spray nozzle spraying liquid; a waste liquid discharger storing waste liquid including a part of the exhaust gas; and a restrictor provided between the spray nozzle and the waste liquid discharger, the restrictor having a second opening area smaller than the first opening area.

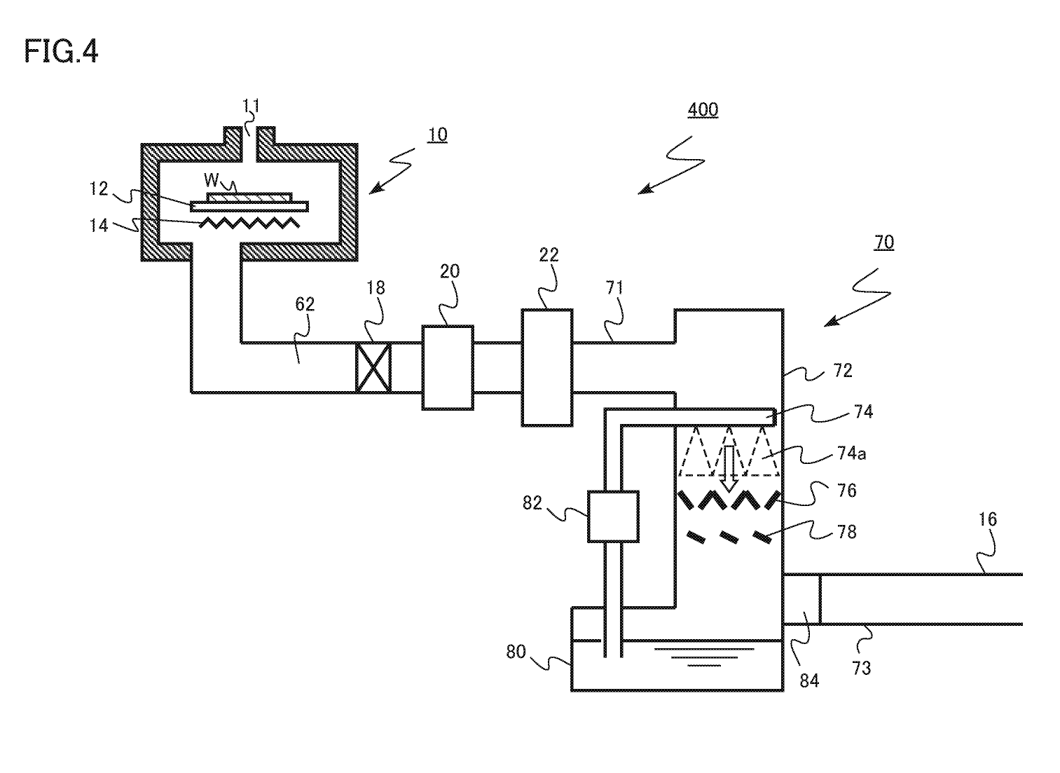

FIG. 4 is a schematic diagram of an exemplary exhaust gas treatment apparatus according to the fourth embodiment. An example is illustrated in which an exhaust gas treatment apparatus 70 according to the fourth embodiment is applied to a film forming apparatus 400 for manufacturing a semiconductor device. The film forming apparatus 400 is a film forming apparatus 400 of single-wafer type for an epitaxial film growth.

The film forming apparatus 400 includes a reaction chamber 10 (process chamber), a gas supply port 11, a stage 12, a heater 14, a discharging unit 16, a pressure regulating valve 18, an exhaust pump 20, a detoxifying device 22, the exhaust gas treatment apparatus 70, and an exhaust pipe 62. The exhaust gas treatment apparatus 70 includes an exhaust gas introducing unit 71, a spray tower 72, an exhaust gas lead-out unit 73, a spray nozzle 74, a restrictor 76, a capturing plate 78 (member), a circulation liquid tank 80 (waste liquid discharger), a circulating pump 82, and an exhaust fan 84.

In the reaction chamber 10, the stage 12 and the heater 14 are provided. A wafer W is placed on the stage 12. The heater 14 heats the wafer W.

The gas supply port 11 is provided in an upper portion of the reaction chamber 10. Source gas is supplied from the gas supply port 11 into the reaction chamber 10.

The reaction chamber 10 is decompressed to a desired pressure at the time of film formation. Exhaust gas including source gas which has not consumed in the reaction chamber 10 and reaction by-products generated by reaction is discharged from the reaction chamber 10 to the exhaust pipe 62.

The exhaust pump 20 is provided between the exhaust pipe 62 and the discharging unit 16. The exhaust pump 20 decompresses the reaction chamber 10. The exhaust pump 20 is, for example, a vacuum pump.

The pressure regulating valve 18 is provided between the exhaust pipe 40 and the exhaust pump 20. The pressure regulating valve 18 can regulate the pressure in the reaction chamber 10 to a desired pressure.

The detoxifying device 22 is provided between the exhaust pump 20 and the discharging unit 16. The detoxifying device 22 is, for example, a combustion-type detoxifying device. The detoxifying device 22 detoxifies the exhaust gas discharged from the reaction chamber 10.

The exhaust gas treatment apparatus 70 is provided between the detoxifying device 22 and the discharging unit 16. The exhaust gas treatment apparatus 70 is a wet scrubber. The exhaust gas treatment apparatus 70 has a function for removing solid particles and acid gas included in the exhaust gas.

The exhaust gas treatment apparatus 70 includes the exhaust gas introducing unit 71, the spray tower 72, the exhaust gas lead-out unit 73, the spray nozzle 74, the restrictor 76, the capturing plate 78, the circulation liquid tank 80, the circulating pump 82, and the exhaust fan 84.

The exhaust gas is introduced from the exhaust gas introducing unit 71 into the spray tower 72, and the exhaust gas processed by the exhaust gas treatment apparatus 70 is led out from the exhaust gas lead-out unit 73.

The spray tower 72 has, for example, a cylindrical shape. The spray tower 72 has the first opening area (or first cross-sectional area) in a cross section in the direction perpendicular to the moving direction of the exhaust gas (white arrow in FIG.

The spray nozzle 74 ejects liquid 74a in a mist form into the spray tower 72. The liquid is, for example, water. For example, the acidic gas in the exhaust gas is dissolved in the liquid 74a. Furthermore, for example, vapor (water vapor) of the liquid 74a is condensed as using the solid particle as a nucleus, and the solid particles are taken in the liquid 74a.

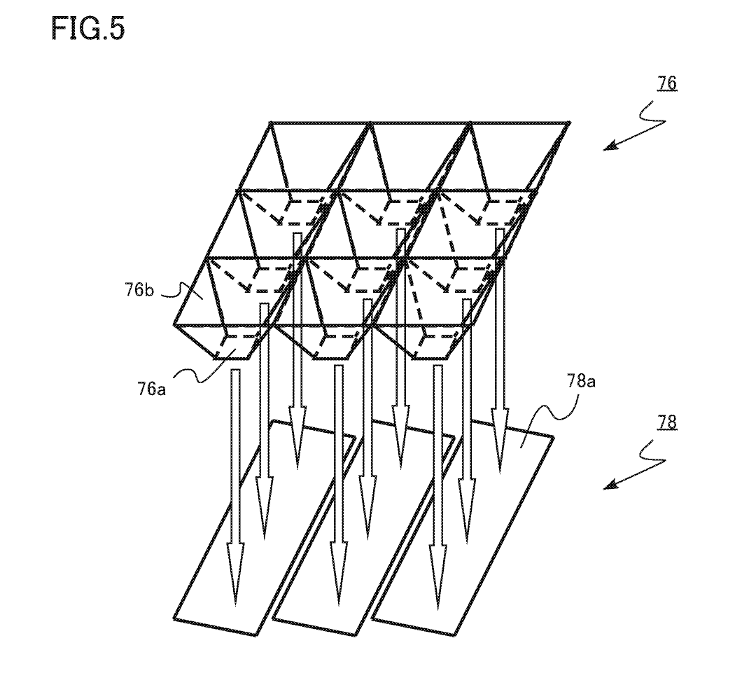

FIG. 5 is a schematic diagram of an example of the restrictor 76 and the capturing plate 78 according to the fourth embodiment.

The restrictor 76 has a plurality of openings 76a and side walls 76b respectively surrounding the openings 76a. The restrictor 76 has the second opening area (or second cross-sectional area) in the cross section in the direction perpendicular to the moving direction of the exhaust gas (white arrows in FIGS. 4 and 5). In a case where the restrictor 76 has the openings 76a, the second opening area is the total sum of the opening areas of the openings 76a.

The second opening area is smaller than the first opening area. For example, the second opening area is equal to or larger than 2.5% and equal to or smaller than 20% of the first opening area.

The side wall 76b has an inclined surface inclined with respect to the moving direction of the exhaust gas (white arrows in FIGS. 4 and 5). The side wall 76b has forward tapered inclination toward the opening 76a. Since the side wall 76b has the forward tapered inclination, the liquid 74a attached to the side wall 76b flows down toward the opening 76a.

The restrictor 76 has a function for accelerating the flow of the exhaust gas in the spray tower 72.

The number of openings 76a provided in the restrictor 76 is nine in FIG. 5. However, the number is not limited to nine. For example, the number of openings 76a may be one.

The capturing plate 78 is provided between the restrictor 76 and the circulation liquid tank 80. The capturing plate 78 has inclined surfaces 78a facing to the moving direction of the exhaust gas (white arrows in FIGS. 4 and 5). An angle between the inclined surface 78a and the moving direction of the exhaust gas is, for example, equal to or more than 10 degrees and equal to or less than 80 degrees.

The capturing plate 78 has a function for capturing the solid particles included in the exhaust gas. The solid particles in the exhaust gas accelerated by the restrictor 76 are caught by colliding with the capturing plate 78. The solid particles caught by the capturing plate 78 flow down along the inclined surface 78a together with the liquid 74a enclosing the solid particles or the liquid 74a attached to the inclined surface 78a and are stored in the circulation liquid tank 80.

The liquid 74a stored in the circulation liquid tank 80 is circulated by the circulating pump 82. The circulated liquid 74a is ejected from the spray nozzle 74 into the spray tower 72.

The exhaust fan 84 has a function for discharging the exhaust gas processed by the exhaust gas treatment apparatus 70 from the exhaust gas lead-out unit 73. Furthermore, the exhaust fan 84 decompresses the spray tower 72.

Next, functions and effects of the exhaust gas treatment apparatus 70 according to the fourth embodiment are described.

In a general film forming apparatus, the exhaust gas including the reaction by-product gas and the source gas which has not been used to form a film is discharged from the reaction chamber to the outside of the manufacturing apparatus through the exhaust pipe, the exhaust pump, the detoxifying device, and the like.

As the exhaust gas is discharged from the reaction chamber and passes through the exhaust pipe, the exhaust gas is condensed by being cooled and changed to the droplets, and is sublimated to be the solid particles. There has been a problem in that the droplets and the solid particles cause clogging of the exhaust pipe and a failure of the exhaust pump.

If the exhaust pipe is clogged or the exhaust pump fails, it is necessary to maintain the manufacturing apparatus, and an operation rate of the manufacturing apparatus is deteriorated. The droplets and the solid particles derived from the exhaust gas include a substance which generates harmful gas and a substance having ignition properties, which may risk the maintenance work. Therefore, it is desired to prevent the clogging of the exhaust pipe and the failure of the exhaust pump due to the droplets and the solid particles derived from the exhaust gas.

To detoxify the exhaust gas, there is a case where a detoxifying device is provided in the film forming apparatus. However, there is a problem in that solid particles are generated as a product and the exhaust pipe is clogged in a detoxifying process by the detoxifying device.

In the exhaust gas treatment apparatus 70 according to the fourth embodiment, the restrictor 76 and the capturing plate 78 are provided in the spray tower 72. By accelerating the solid particles in the exhaust gas by the restrictor 76 and capturing the solid particles by making the solid particles collide with the capturing plate 78, an efficiency of capturing the solid particles is improved.

For example, when the exhaust gas treatment apparatus 70 does not include the restrictor 76 and the capturing plate 78, small solid particles may be discharged outside the exhaust gas treatment apparatus on the flow of the exhaust gas. In the exhaust gas treatment apparatus 70 according to the fourth embodiment, the small solid particles can be caught. Therefore, it is desired to prevent the clogging of the exhaust pipe and the failure of the exhaust pump due to the droplets and the solid particles derived from the exhaust gas.

For example, in a case where the film forming apparatus 400 forms a silicon epitaxial film, a silicon-based gas, for example, dichlorosilane (SiH₂Cl₂) is used as source gas. The silicon-based gas included in the exhaust gas is burned in the combustion-type detoxifying device 22 and silicon oxide is generated to detoxify the silicon-based gas. A boiling point of silicon oxide is high, and silicon oxide is attached to the exhaust pipe on the downstream side of the detoxifying device 22 and the like as a solid product. This causes a problem.

In the exhaust gas treatment apparatus 70 according to the fourth embodiment, for example, it is possible to efficiently remove solid particles of silicon oxide generated in the detoxifying device 22.

From the viewpoint of efficiently capturing the solid particles and efficiently flowing the caught solid particles into the circulation liquid tank 80, an inclination angle of the inclined surface 78a of the capturing plate 78 with respect to the moving direction of the exhaust gas (white arrows in FIGS. 4 and 5) is preferably equal to or more than 10 degrees and equal to or less than 80 degrees, and more preferably, equal to or more than 30 degrees and equal to or less than 60 degrees.

Furthermore, for example, the inclination angle of the inclined surface 78a of the capturing plate 78 with respect to the moving direction of the exhaust gas (white arrows in FIGS. 4 and 5) can be set to 90 degrees, that is, perpendicular to the moving direction of the exhaust gas so as to catch the solid particles. In this case, for example, it is also possible to provide a scraper for removing solid particles which are newly accumulated on the surface of the capturing plate 78.

The second opening area of the restrictor 76 is preferably equal to or larger than 2.5% and equal to or smaller than 20% of the first opening area of the spray tower 72. When the area is smaller than the above range, there is a possibility that the flow of the exhaust gas stops at the opening 76a of the restrictor 76. Furthermore, when the area exceeds the above range, the solid particles are not sufficiently accelerated, and there is a possibility that the efficiency of capturing the solid particles is not improved.

In the exhaust gas treatment apparatus 70 according to the fourth embodiment, by decompressing the spray tower 72 of the exhaust gas treatment apparatus 70 by the exhaust fan 84, the speeds of the exhaust gas and the solid particles in the exhaust gas can be increased. By increasing the speed of the solid particles, the efficiency of capturing the solid particles in the exhaust gas can be further improved.

As described above, according to the fourth embodiment, there can be provided an exhaust gas treatment apparatus capable of efficiently removing the solid particles and preventing the clogging of the exhaust pipe and the failure of the exhaust pump.

### Fifth Embodiment

A fifth embodiment is different from the fourth embodiment in that the exhaust gas treatment apparatus is applied to a dry etching apparatus. The description overlapped with the fourth embodiment may be partially omitted.

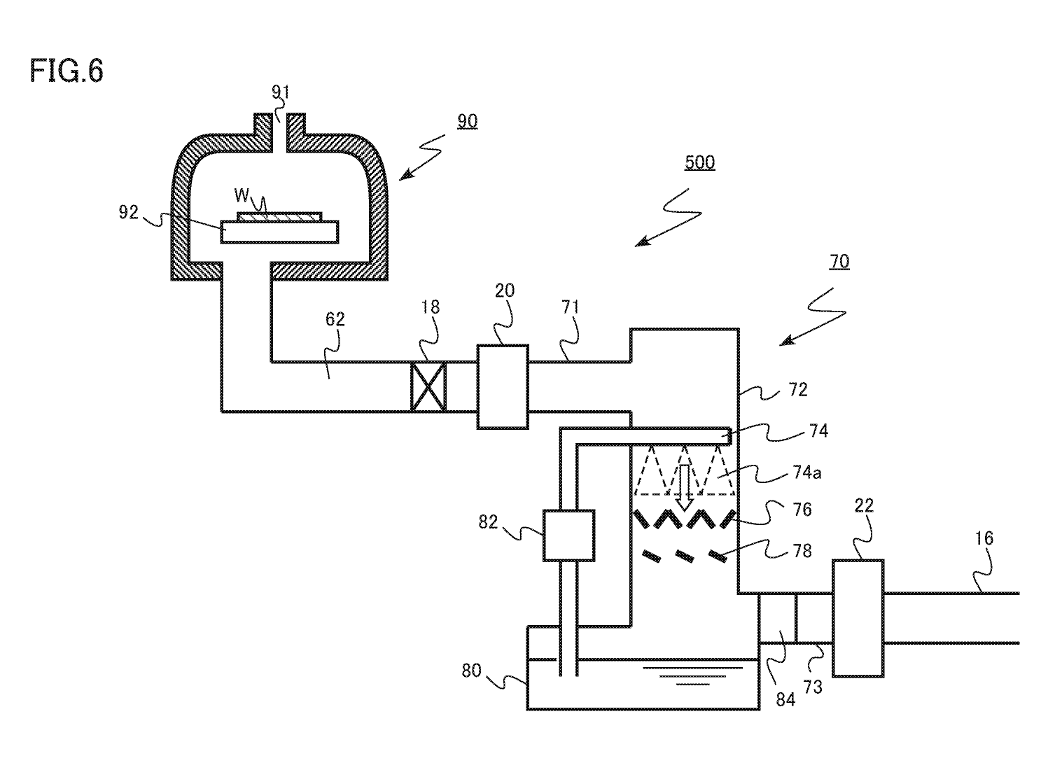

FIG. 6 is a schematic diagram of an exemplary exhaust gas treatment apparatus according to the fifth embodiment. An example is illustrated in which an exhaust gas treatment apparatus 70 according to the fifth embodiment is applied to an etching apparatus 500 for manufacturing a semiconductor device. The etching apparatus 500 is an inductive coupled reactive ion etching apparatus.

The etching apparatus 500 includes a dielectric chamber 90 (process chamber), a gas supply port 91, a stage 92, a discharging unit 16, a pressure regulating valve 18, an exhaust pump 20, a detoxifying device 22, an exhaust gas treatment apparatus 70, and an exhaust pipe 62. The exhaust gas treatment apparatus 70 includes an exhaust gas introducing unit 71, a spray tower 72, an exhaust gas lead-out unit 73, a spray nozzle 74, a restrictor 76, a capturing plate 78 (member), a circulation liquid tank 80 (waste liquid discharger), a circulating pump 82, and an exhaust fan 84.

The stage 92 is provided in the dielectric chamber 90. A wafer W is placed on the stage 92. Etching gas is introduced from the gas supply port 91 in an upper portion of the dielectric chamber 90 to ionize the etching gas. The ionization of the etching gas is performed by an inductive coupling method in which high-frequency power is supplied to a dielectric coil (not shown). The ionized reactive gas is fed onto the wafer W, and the film on the surface of the wafer. W is etched.

The inside of the dielectric chamber 90 is decompressed to a desired pressure at the time of the etching. From the dielectric chamber 90, exhaust gas including the etching gas which has not been consumed in the dielectric chamber 90 and reaction by-products generated by the reaction is discharged to the exhaust pipe 62.

The exhaust pump 20 is provided between the exhaust pipe 62 and the discharging unit 16. The exhaust pump 20 decompresses the reaction chamber 10. The exhaust pump 20 is, for example, a vacuum pump.

The pressure regulating valve 18 is provided between the exhaust pipe 62 and the exhaust pump 20. The pressure regulating valve 18 can regulate the pressure in the dielectric chamber 90 to a desired pressure.

The exhaust gas treatment apparatus 70 is provided between the exhaust pump 20 and the discharging unit 16. The exhaust gas treatment apparatus 70 is a wet scrubber. The exhaust gas treatment apparatus 70 has a function for removing solid particles included in the exhaust gas and acid gas.

The detoxifying device 22 is provided between the exhaust gas treatment apparatus 70 and the discharging unit 16. The detoxifying device 22 is, for example, a combustion-type detoxifying device. The detoxifying device 22 detoxifies the exhaust gas discharged from the dielectric chamber 90.

The exhaust fan 84 has a function for discharging the exhaust gas processed by the exhaust gas treatment apparatus 70 from the exhaust gas introducing unit 71. Furthermore, the exhaust fan 84 decompresses the spray tower 72.

For example, in a case where deep trenches are formed in a silicon wafer, the Bosch process method is applied in some cases. The Bosch process method is a method of alternately repeating a dry etching process using a sulfur fluoride gas such as SF₆ and a forming process (passivation process) of a side wall protective film using a fluorocarbon gas such as CHF₃ and C₄F₈. Etching with high anisotropy can be realized by the Bosch process method.

However, since the side wall protective film is formed in the Bosch process method, a reaction by-product having a high boiling point is generated, and the solid particles are generated in the exhaust pipe. There is a problem in that the exhaust pipe is clogged by the solid particles.

In the exhaust gas treatment apparatus 70 according to the fifth embodiment, the restrictor 76 and the capturing plate 78 are provided in the spray tower 72. By accelerating the solid particles in the exhaust gas by the restrictor 76 and capturing the solid particles by making the solid particles collide with the capturing plate 78, an efficiency of capturing the solid particles is improved. Therefore, for example, the efficiency of capturing the solid particles generated by the Bosch process method is improved.

As described above, according to the fifth embodiment, there can be provided an exhaust gas treatment apparatus capable of efficiently removing the solid particles and preventing the clogging of the exhaust pipe and the failure of the exhaust pump.

In the first to fifth embodiments, the manufacturing apparatus for manufacturing the semiconductor device has been described as an example. However, the present disclosure can be applied to a manufacturing apparatus for manufacturing a liquid crystal device.

While certain embodiments have been described, these embodiments have been presented by way of example only, and are not intended to limit the scope of the inventions. Indeed, the manufacturing apparatus and the exhaust gas treatment apparatus described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A manufacturing apparatus of a semiconductor device or a liquid crystal device, comprising:
a process chamber discharging exhaust gas;
a waste liquid discharger discharging waste liquid including a part of the exhaust gas;
a first pipe provided between the process chamber and the waste liquid discharger, the first pipe having a first opening area in a cross section in a direction perpendicular to a moving direction of the exhaust gas;
a second pipe provided between the first pipe and the waste liquid discharger, the second pipe having a second opening area smaller than the first opening area in a cross section in the direction perpendicular to the moving direction of the exhaust gas; and
a third pipe connected to the first pipe, the third pipe supplying a condensing agent having a normal boiling point of equal to or higher than 25° C. to the first pipe.

2. The manufacturing apparatus according to claim 1, further comprising:
a temperature adjuster adjusting a temperature in the first pipe.

3. The manufacturing apparatus according to claim 1, further comprising:
a heater heating the condensing agent before supplying the condensing agent to the first pipe.

4. The manufacturing apparatus according to claim 1, further comprising:
a member provided between the second pipe and the waste liquid discharger, the member having a surface facing to the moving direction of the exhaust gas.

5. A manufacturing apparatus of a semiconductor device or a liquid crystal device, comprising:
a process chamber discharging exhaust gas;
a waste liquid discharger discharging waste liquid including a part of the exhaust gas;
a discharging unit discharging a remaining part of the exhaust gas;
a first pipe provided between the process chamber and the waste liquid discharger, the first pipe having a first opening area in a cross section in a direction perpendicular to a moving direction of the exhaust gas;
a second pipe provided between the first pipe and the waste liquid discharger, the second pipe having a second opening area smaller than the first opening area in a cross section in the direction perpendicular to the moving direction of the exhaust gas;
a first pressure regulator provided between the process chamber and the first pipe, the first pressure regulator controlling a pressure in the process chamber; and
a second pressure regulator provided between the waste liquid discharger and the discharging unit, the second pressure regulator controlling a pressure in the first pipe.

6. The manufacturing apparatus according to claim 5, further comprising:
a chiller cooling an inside of the first pipe.

7. The manufacturing apparatus according to claim 5, further comprising:
a member provided between the second pipe and the waste liquid discharger, the member having a surface facing to the moving direction of the exhaust gas.

8. An exhaust gas treatment apparatus comprising:
a spray tower having a first opening area in a cross section in a direction perpendicular to a moving direction of exhaust gas;
a spray nozzle provided in the spray tower, the spray nozzle spraying liquid;
a waste liquid discharger storing waste liquid including a part of the exhaust gas; and
a restrictor provided between the spray nozzle and the waste liquid discharger, the restrictor having a second opening area smaller than the first opening area.

9. The exhaust gas treatment apparatus according to claim 8, further comprising:
a member provided between the restrictor and the waste liquid discharger, the member having a surface facing to the moving direction of the exhaust gas.

10. The exhaust gas treatment apparatus according to claim 9, wherein
the second opening area is equal to or smaller than 20% of the first opening area.
